(19) United States
(12) Patent Application Publication
(10) Pub. No.: US 2005/0237105 A1
(43) Pub. Date: Oct. 27, 2005

(54) Self-biased bandgap reference voltage generation circuit insensitive to change of power supply voltage

(75) Inventor: Kwang-Il Park, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/115,832

(22) Filed: Apr. 27, 2005

(30) Foreign Application Priority Data
Apr. 27, 2004 (KR) 2004-29183

(51) Int. Cl. H03F 3/45

(52) U.S. Cl. 327/539

(57) ABSTRACT

A bandgap reference voltage generation circuit insensitive to a change of a power supply voltage includes an OP amplifier and first through third PMOS transistors and generates a reference voltage, where the OP amplifier supplies an output voltage as a bias voltage and compares first and second voltages, the first through third PMOS transistors are gated to an output voltage of the OP amplifier and deliver currents of identical levels, the first voltage corresponds to a current that is passed through the first PMOS transistor and connected to a first resistor and a first diode which are connected to each other in parallel, the second voltage is applied to a second resistor connected in parallel to the second PMOS transistor, a third resistor serially connected to the second PMOS transistor, and a second diode group serially connected to the third resistor, the reference voltage is a voltage corresponding to a current that is passed through the third PMOS transistor and applied to a fourth resistor, such that the bandgap reference voltage generation circuit generates a stable reference voltage according to a ratio of resistance values of the resistors instead of absolute values of the resistance values without being affected by the power supply voltage change.

### CROSS-REFERENCE TO RELATED APPLICATION

This application claims foreign priority under 35 U.S.C. § 119 to Korean Patent Application No. 2004-29183, filed on Apr. 27, 2004, in the Korean Intellectual Property Office, the disclosure of which is incorporated herein by reference in its entirety.

### BACKGROUND OF THE INVENTION

1. Field of the Invention

The present disclosure relates to a semiconductor integrated circuit, and more particularly, to a self-biased band-gap reference voltage generation circuit insensitive to a change of a power supply voltage.

2. Description of the Related Art

A band-gap reference voltage generation circuit (hereinafter, referred to as a BGR circuit) is used in a semiconductor integrated circuit and provides a stable bias voltage. A BGR circuit usually provides a reference voltage for an analog-to-digital converter (ADC) or a digital-to-analog converter (DAC) and has stable characteristics against a temperature or a process change. With the recent widespread popularity of portable devices that are operated by batteries, demands are increasing for low power consumption and low voltage operation. Hence, as the level of a power supply voltage VCC decreases to about 1.5V to 2.0V, the level of a reference voltage generated by a BGR circuit is also expected to decrease to about 1.25V to 1.0V.

FIG. 1 is a circuit diagram of a conventional BGR circuit 120. Referring to FIG. 1, the BGR circuit 120 includes an OP AMP 122 that is driven by a bias voltage V_{bias} provided by a bias circuit 110, diodes D1 and D2, resistors R1, R2, R3 and R4, and transistors P1, P2, P3 and N1. The OP AMP 122 is controlled so that voltages Vi and Vib become equal. Currents Io, Iob and Iref with substantially identical levels flow through first, second and third PMOS transistors P1, P2 and P3, respectively, which are driven by an output Vo of the OP AMP 122.

In the bias circuit 110, a fourth PMOS transistor P4 and a resistor R5 are diode-connected to each other and serially connected between a power supply voltage VDD and a ground voltage VSS. A connection node between the fourth PMOS transistor P4 and the resistor R5 is provided to the bias voltage V_{bias} of the OP AMP 122. The bias voltage V_{bias} is represented as a voltage level obtained by subtracting a threshold voltage Vth of the fourth PMOS transistor P4 from the power supply voltage VDD. Hence, the level of the bias voltage V_{bias} may vary according to a level of the power supply voltage VDD.

When the level of the bias voltage V_{bias} is changed according to the level of the power supply voltage VDD, the operational currents Io, Iob, and Iref of the OP AMP 122 are also changed. Particularly, the change of the operation current Iref causes a change of the reference voltage Vref.

Hence, a BGR circuit insensitive to a change of the level of the power supply voltage VDD is desired.

### SUMMARY OF THE INVENTION

The present disclosure provides a BGR circuit substantially insensitive to a change of the level of a power supply voltage.

According to an aspect of the present disclosure, there is provided an exemplary bandgap reference voltage generation circuit for generating a reference voltage. The circuit includes an OP amplifier for supplying an output voltage as a bias voltage and comparing first and second voltages, a first NMOS transistor connected between the output voltage of the OP amplifier and a ground voltage and having a gate connected to a reset signal, a first PMOS transistor connected between a power supply voltage and the first voltage and having a gate connected to the output voltage of the OP amplifier, a second PMOS transistor connected between the power supply voltage and the second voltage and having a gate connected to the output voltage of the OP amplifier, a third PMOS transistor connected between the power supply voltage and the reference voltage and having a gate connected to the output voltage of the OP amplifier, a first resistor connected between the first voltage and a ground voltage, a first diode connected between the first voltage and the ground voltage, a second resistor connected between the second voltage and the ground voltage, a third resistor and a second diode group serially connected between the second voltage and the ground voltage, and a fourth resistor connected between the reference voltage and the ground voltage.

According to another aspect of the present disclosure, there is provided an exemplary bandgap reference voltage generation circuit for generating a reference voltage. The circuit includes an OP amplifier for supplying an output voltage as a bias voltage and comparing first and second voltages, a first NMOS transistor connected between the output voltage of the OP amplifier and a ground voltage and having a gate connected to a reset signal, a first PMOS transistor connected between a power supply voltage and the first voltage and having a gate connected to the output voltage of the OP amplifier, a second PMOS transistor connected between the power supply voltage and the second voltage and having a gate connected to the output voltage of the OP amplifier, a third PMOS transistor connected between the power supply voltage and the reference voltage and having a gate connected to the output voltage of the OP amplifier, a first resistor connected between the first voltage and a ground voltage, a fifth resistor and a first diode serially connected between the first voltage and the ground voltage, a second resistor connected between the second voltage and the ground voltage, a third resistor and a second diode group serially connected between the second voltage and the ground voltage, and a fourth resistor connected between the reference voltage and the ground voltage.

The exemplary OP amplifier includes a fourth PMOS transistor having a source connected to the power supply voltage and a gate connected to the output voltage of the OP amplifier, fifth and sixth PMOS transistors having sources commonly connected to a drain of the fourth PMOS transistor and gates connected to the first and second voltages, respectively, second and third NMOS transistors connected between the fifth PMOS transistor and the ground voltage and between the sixth PMOS transistor and the ground voltage, respectively, and each of the second and third NMOS transistors having a drain and a gate connected to each other, a fourth NMOS transistor having a gate connected to the gate of the second NMOS transistor and a source connected to the ground voltage and constituting a current mirror together with the second NMOS transistor, a fifth NMOS transistor having a drain connected to the output voltage of the OP amplifier, a gate connected to the gate of the third NMOS transistor, and a source connected to the ground voltage and constituting a current mirror together with the third NMOS transistor, a seventh PMOS transistor having a source connected to the power supply voltage and a drain and a gate that are connected to a drain of the fourth NMOS transistor, and an eighth PMOS transistor having a source connected to the power supply voltage, a drain connected to the output voltage of the OP amplifier, and a gate connected to the gate of the seventh PMOS transistor and constituting a current mirror together with the seventh PMOS transistor.

The exemplary second diode group comprises a plurality of diodes connected in parallel between the third resistor and the ground voltage.

Thus, the exemplary bandgap reference voltage generation circuit generates a stable reference voltage according to a ratio of resistance values of the resistors instead of absolute values of the resistance values without being affected by the power supply voltage change.

### BRIEF DESCRIPTION OF THE DRAWINGS

The above and other features and advantages of the present disclosure will become more apparent by describing in detail exemplary embodiments thereof with reference to the attached drawings, in which:

FIG. 1 is a circuit diagram of a conventional band-gap reference voltage generation circuit;

FIG. 2 is a circuit diagram of a band-gap reference voltage generation circuit according to an embodiment of the present disclosure;

FIG. 3 is a detailed circuit diagram of the band-gap reference voltage generation circuit of FIG. 2; and

FIG. 4 is a circuit diagram of a band-gap reference voltage generation circuit according to another embodiment of the present disclosure.

### DETAILED DESCRIPTION OF PREFERRED EMBODIMENTS

The attached drawings for illustrating preferred embodiments of the present disclosure are referred to in order to gain a sufficient understanding of the present disclosure, the merits thereof, and the features achieved by implementations of the present disclosure.

Hereinafter, the present disclosure will be described in detail by explaining preferred embodiments thereof with reference to the attached drawings. Like reference numerals in the drawings may be used to denote like elements.

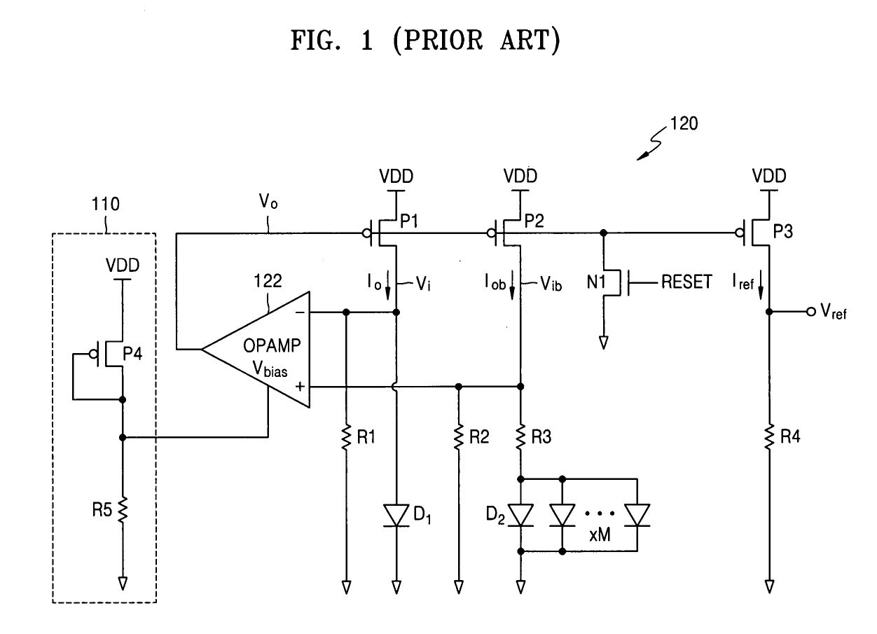

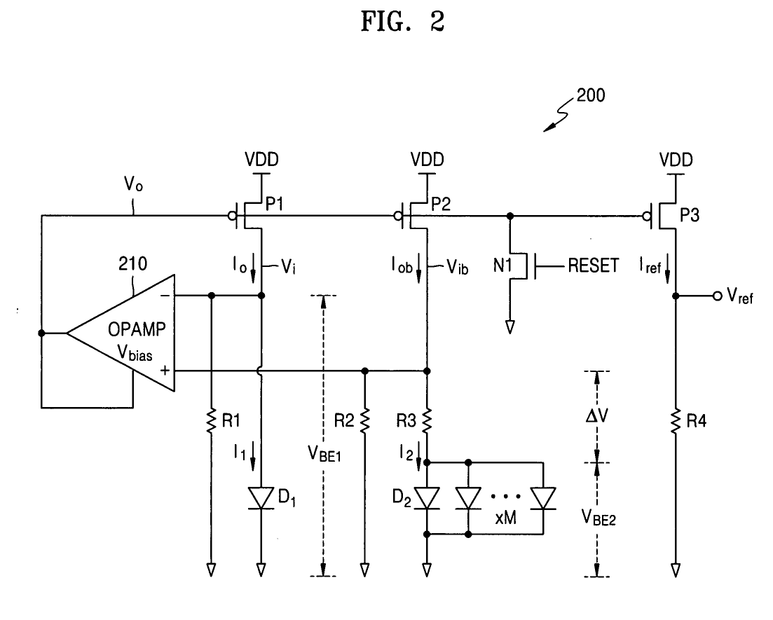

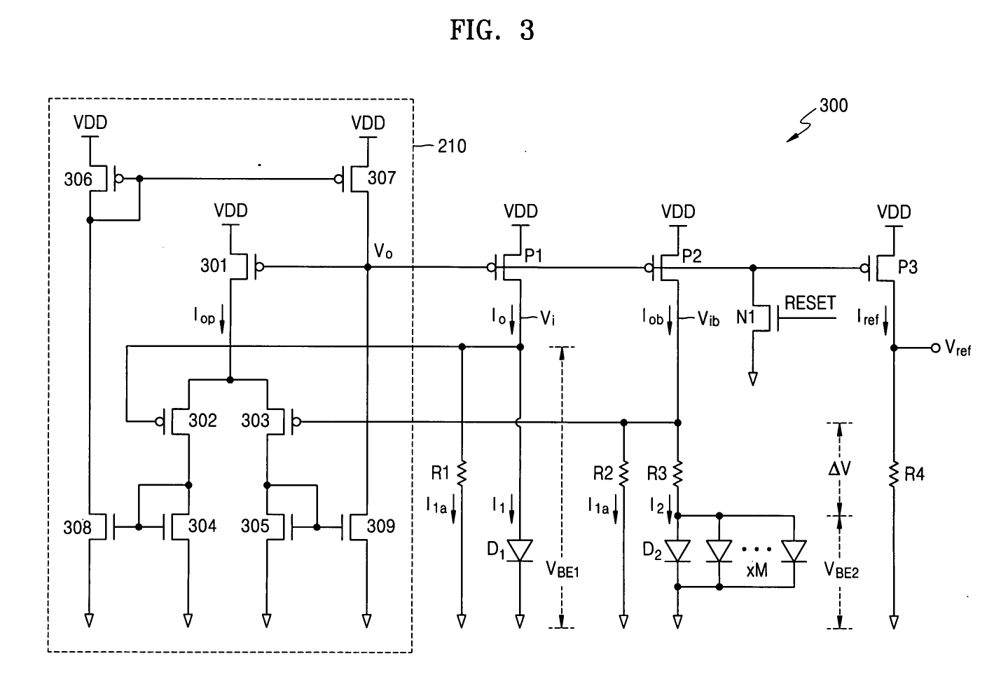

FIG. 2 is a circuit diagram of a band-gap reference voltage generation (BGR) circuit 200 according to an embodiment of the present disclosure. Referring to FIG. 2, the BGR circuit 200 has an OP AMP 210, whose bias voltage V_{bias} is connected to an output voltage Vo of the OP AMP 210. This is different from the conventional BGR circuit of FIG. 1, in which the bias voltage V_{bias} of the OP AMP 122 is supplied from the bias circuit 110. A BGR circuit 300 including a detailed circuit diagram of an exemplary OP AMP 210 is illustrated in FIG. 3.

Referring to FIG. 3, the OP AMP 210 is a differential amplifier. The OP AMP 210 includes PMOS transistors 301, 302, 303, 306, and 307 and NMOS transistors 304, 305, 308, and 309. The PMOS transistors 302 and 303 receive first and second voltages Vi and Vib through their gates, respectively. The PMOS transistor 301 is connected between a power supply voltage VDD and a source shared by the PMOS transistors 302 and 303. The NMOS transistors 304 and 308 constitute a first current mirror, the NMOS transistors 305 and 309 constitute a second current mirror, and the PMOS transistors 306 and 307 constitute a third current mirror. The first current mirror is connected to a drain of the PMOS transistor 302, the second current mirror is connected to a drain of the PMOS transistor 303, and the third current mirror is connected to both the NMOS transistors 308 and 309.

The OP AMP 210 is driven by an operational current loop, which flows through the PMOS transistor 301 gated to the output voltage Vo of the OP AMP 210. The operational current loop flows when the output voltage Vo becomes logic low through the first NMOS transistor N1 turned on in response to a reset signal RESET.

The BGR circuit 300 further includes first, second and third PMOS transistors P1, P2 and P3 with identical dimensions, first and second resistors R1 and R2 having identical resistances, a first diode D1, M second diodes D2 (where M is an integer greater than 0), a third resistor R3 and a fourth resister R4.

The first PMOS transistor P1 is connected between a power supply voltage VDD and the first voltage Vi and has a gate connected to the output voltage Vo of the OP AMP 210. The second PMOS transistor P2 is connected between the power supply voltage VDD and the second voltage Vib and has a gate connected to the output voltage Vo of the OP AMP 210. The third PMOS transistor P3 is connected between the power supply voltage VDD and a reference voltage Vref and has a gate connected to the output voltage Vo of the OP AMP 210. The fourth resistor is connected between the reference voltage Vref and a ground voltage VSS.

The first resistor R1 is connected between the first voltage Vi and a ground voltage VSS, and the first diode D1 is connected between the first voltage Vi and the ground voltage VSS. The second resistor R2 is connected between the second voltage Vib and the ground voltage VSS, and the third resistor R3 is serially connected with a group of the second diodes D2 between the second voltage Vib and the ground voltage VSS. The second diodes D2 are connected to one another in parallel.

Operation of the BGR circuit 300 will now be described. Since the first, second and third PMOS transistors P1, P2 and P3 have substantially identical dimensions, and the first and second resistors R1 and R2 have substantially identical resistances, the first voltage Vi applied to both ends of the first resistor R1 has the same level as that of the second voltage Vib applied to both ends of the second resistor R2.
Vi=Vib (1)

Hence, the gates of the first, second and third PMOS transistors P1, P2 and P3 are commonly connected to the output voltage Vo of the OP AMP 210, such that the first, second and third currents Io, Iob and Iref have almost the same levels as expressed in Equation (2):
Io=Iob=Iref (2)

Since Io is equal to I1a+I1 and Iob is equal to I2a+I2, I1a is equal to I2a. Accordingly, Equation 3 is established:
I1=I2 (3)
ΔV=V_{BE1}−V_{BE2}=V_{T}·ln(M) (4)
wherein V_{T} denotes a thermal voltage and has a thermal coefficient of 0.086 mV/° C.

Since I2 is proportional to V_{T}, Equation (5) is established:

$$I2 = \frac{Δ V}{R3} \qquad ( 5 )$$

Since I2a is proportional to V_{BE1}, Equation (6) is established:

$$I2a = \frac{{V}_{BE1}}{R2} \qquad ( 6 )$$

Since the current Iob is a sum of I2 and I2a and mirrored to the current Iref, Equation (7) is established:
Iref=lob=I2+I2a (7)

Hence, the reference voltage Vref, which is output by the BGR circuit 300, is calculated by Equation (8):

$$Vref = R4 ( \frac{Δ V}{R3} + \frac{{V}_{BE1}}{R2} ) \qquad ( 8 )$$

In other words, the reference voltage Vref is determined using a ratio of resistances of the resistors R2, R3 and R4 and is hardly affected by absolute values of the resistances.

Accordingly, in the BGR circuit 300, the output voltage Vo of the OP AMP 210, whose level is changed to a logic low level according to a reset signal RESET, is applied to a bias voltage of the OP AMP 210 and operates the OP AMP 210. Thus, the BGR circuit 300 generates a stable reference voltage Vref according to a ratio of the first, second and third resistors R1, R2 and R3 without an influence of a change of the power supply voltage VDD upon an operation of the OP AMP 210.

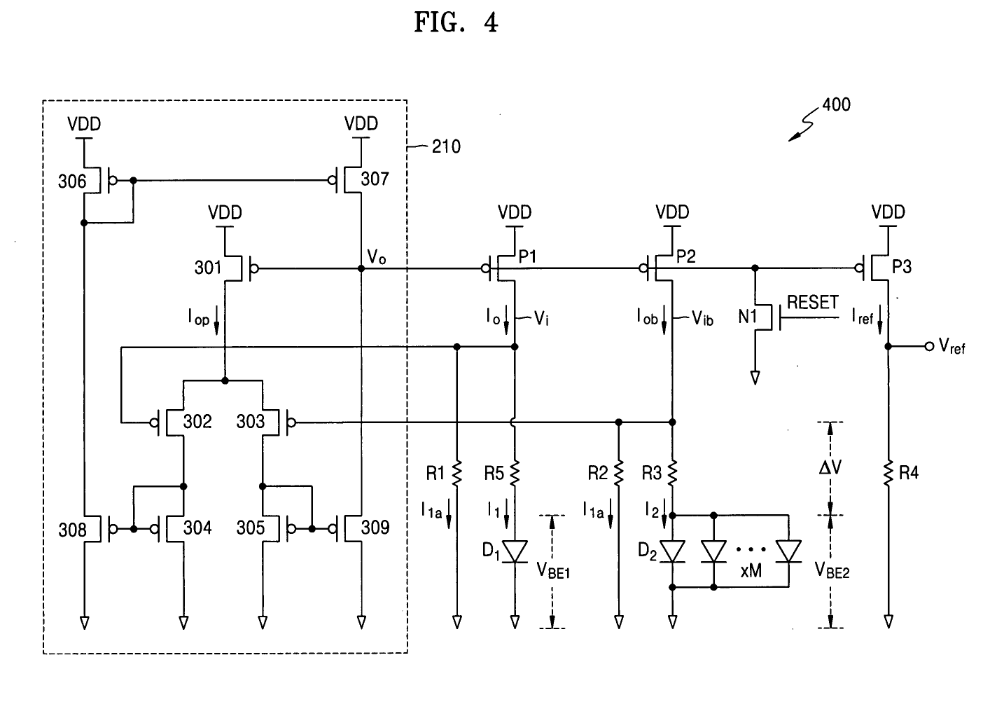

FIG. 4 is a circuit diagram of a BGR circuit 400 according to another embodiment of the present disclosure. Referring to FIG. 4, the BGR circuit 400 is different from the BGR circuit 300 of FIG. 3 in that a fifth resistor R5 and a first diode D1 are serially connected between a first voltage Vi and a ground voltage VSS. The fifth resistor R5 reduces the amounts of first and second currents I1 and I2, so Equations (1) through (8) established by the operation of the BGR circuit 300 are equally applied to the BGR circuit 400.

While the present invention has been particularly shown and described with reference to exemplary embodiments thereof, it will be understood by those of ordinary skill in the pertinent art that various changes in form and details may be made therein without departing from the spirit and scope of the present invention, as defined by the following claims.

1. A bandgap reference voltage generation circuit for generating a reference voltage, comprising:
an OP amplifier supplying an output voltage as a bias voltage and comparing first and second voltages;
a first NMOS transistor connected between the output voltage of the OP amplifier and a ground voltage and having a gate connected to a reset signal;
a first PMOS transistor connected between a power supply voltage and the first voltage and having a gate connected to the output voltage of the OP amplifier;
a second PMOS transistor connected between the power supply voltage and the second voltage and having a gate connected to the output voltage of the OP amplifier;
a third PMOS transistor connected between the power supply voltage and the reference voltage and having a gate connected to the output voltage of the OP amplifier;
a first resistor connected between the first voltage and a ground voltage;
a first diode connected between the first voltage and the ground voltage;
a second resistor connected between the second voltage and the ground voltage;
a third resistor and a second diode group serially connected between the second voltage and the ground voltage; and
a fourth resistor connected between the reference voltage and the ground voltage.

2. The bandgap reference voltage generation circuit of claim 1, wherein the OP amplifier comprises:
a fourth PMOS transistor having a source connected to the power supply voltage and a gate connected to the output voltage of the OP amplifier;
fifth and sixth PMOS transistors having sources commonly connected to a drain of the fourth PMOS transistor and gates connected to the first and second voltages, respectively;
second and third NMOS transistors connected between the fifth PMOS transistor and the ground voltage and between the sixth PMOS transistor and the ground voltage, respectively, and each of the second and third NMOS transistors having a drain and a gate connected to each other;
a fourth NMOS transistor having a gate connected to the gate of the second NMOS transistor and a source connected to the ground voltage and constituting a current mirror together with the second NMOS transistor;
a fifth NMOS transistor having a drain connected to the output voltage of the OP amplifier, a gate connected to the gate of the third NMOS transistor, and a source connected to the ground voltage and constituting a current mirror together with the third NMOS transistor;
a seventh PMOS transistor having a source connected to the power supply voltage and a drain and a gate that are connected to a drain of the fourth NMOS transistor; and
an eighth PMOS transistor having a source connected to the power supply voltage, a drain connected to the output voltage of the OP amplifier, and a gate connected to the gate of the seventh PMOS transistor and constituting a current mirror together with the seventh PMOS transistor.

3. The bandgap reference voltage generation circuit of claim 1, wherein the second diode group comprises a plurality of diodes connected in parallel between the third resistor and the ground voltage.

4. A bandgap reference voltage generation circuit for generating a reference voltage, comprising:
an OP amplifier supplying an output voltage as a bias voltage and comparing first and second voltages;
a first NMOS transistor connected between the output voltage of the OP amplifier and a ground voltage and having a gate connected to a reset signal;
a first PMOS transistor connected between a power supply voltage and the first voltage and having a gate connected to the output voltage of the OP amplifier;
a second PMOS transistor connected between the power supply voltage and the second voltage and having a gate connected to the output voltage of the OP amplifier;
a third PMOS transistor connected between the power supply voltage and the reference voltage and having a gate connected to the output voltage of the OP amplifier;
a first resistor connected between the first voltage and a ground voltage;
a fifth resistor and a first diode serially connected between the first voltage and the ground voltage;
a second resistor connected between the second voltage and the ground voltage;
a third resistor and a second diode group serially connected between the second voltage and the ground voltage; and
a fourth resistor connected between the reference voltage and the ground voltage.

5. The bandgap reference voltage generation circuit of claim 4, wherein the OP amplifier comprises:
a fourth PMOS transistor having a source connected to the power supply voltage and a gate connected to the output voltage of the OP amplifier;
fifth and sixth PMOS transistors having sources commonly connected to a drain of the fourth PMOS transistor and gates connected to the first and second voltages, respectively;
second and third NMOS transistors connected between the fifth PMOS transistor and the ground voltage and between the sixth PMOS transistor and the ground voltage, respectively, and each of the second and third NMOS transistors having a drain and a gate connected to each other;
a fourth NMOS transistor having a gate connected to the gate of the second NMOS transistor and a source connected to the ground voltage and constituting a current mirror together with the second NMOS transistor;
a fifth NMOS transistor having a drain connected to the output voltage of the OP amplifier, a gate connected to the gate of the third NMOS transistor, and a source connected to the ground voltage and constituting a current mirror together with the third NMOS transistor;
a seventh PMOS transistor having a source connected to the power supply voltage and a drain and a gate that are connected to a drain of the fourth NMOS transistor; and
an eighth PMOS transistor having a source connected to the power supply voltage, a drain connected to the output voltage of the OP amplifier, and a gate connected to the gate of the seventh PMOS transistor and constituting a current mirror together with the seventh PMOS transistor.

6. The bandgap reference voltage generation circuit of claim 4, wherein the second diode group comprises a plurality of diodes connected in parallel between the third resistor and the ground voltage.

7. A reference voltage generation circuit comprising:
amplification means for receiving first and second input voltages and amplifying an output voltage as a bias voltage in correspondence with a comparison between the first and second input voltages;
first switch means in signal communication with the amplification means for switching the output voltage to a ground potential in response to a reset;
second switch means in signal communication with the amplification means for switching a power supply voltage to the first input voltage in response to the output voltage;
third switch means in signal communication with the amplification means for switching the power supply voltage to the second input voltage in response to the output voltage; and
fourth switch means in signal communication with the amplification means for switching the power supply voltage to the reference voltage in response to the output voltage.

8. A circuit as defined in claim 7 wherein:
the first switch means comprises an NMOS transistor; and
the second through fourth switch means each comprises a PMOS transistor.

9. A circuit as defined in claim 7, further comprising:
first resistance means in signal communication between the first input voltage and the ground potential;
first diode means in signal communication between the first input voltage and the ground potential;
second resistance means in signal communication between the second input voltage and the ground potential;
third resistance means in signal communication with at least one second diode means between the second input voltage and the ground potential; and
fourth resistance means in signal communication between the reference voltage and the ground potential.

10. A circuit as defined in claim 9, further comprising fifth resistance means in signal communication with the first diode means between the first input voltage and the ground potential.

11. A circuit as defined in claim 7, the amplification means comprising:
fifth switch means in signal communication with the power supply voltage for switching in response to the output voltage of the amplification means;
sixth and seventh switch means in signal communication with the fifth switch means for switching in response to the first and second input voltages, respectively;
eighth and ninth switch means in signal communication between the sixth switch means and the ground voltage and between the seventh switch means and the ground voltage, respectively, for mirroring current;
tenth switch means in signal communication with the eighth switch means and the ground potential for following the mirrored current of the eighth switch means;
eleventh switch means in signal communication with the output voltage of the amplification means, the ninth switch means and the ground potential for following the mirrored current of the ninth switch means;
twelfth switch means in signal communication with the power supply voltage and the tenth switch means for mirroring current; and
thirteenth switch means in signal communication with the power supply voltage and the output voltage of the amplification means, and a gate connected to the gate of the twelfth switch means for following the mirrored current of the twelfth switch means.

12. A circuit as defined in claim 11 wherein:
the fifth, sixth, seventh, twelfth and thirteenth switch means each comprises a PMOS transistor; and
the eighth, ninth, tenth and eleventh switch means each comprises an NMOS transistor.

13. A circuit as defined in claim 11 wherein the fifth through thirteenth switch means each comprises a PMOS transistor.

14. A method of generating a reference voltage, the method comprising:
receiving first and second input voltages and amplifying an output voltage as a bias voltage in correspondence with a comparison between the first and second input voltages;
switching the output voltage to a ground potential in response to a reset;
switching a power supply voltage to the first input voltage in response to the output voltage;
switching the power supply voltage to the second input voltage in response to the output voltage; and
switching the power supply voltage to the reference voltage in response to the output voltage.

15. A method as defined in claim 14 wherein the second through fourth switching steps each comprises switching with an inverting switching device.

16. A method as defined in claim 14, further comprising:
resisting current flow between the first input voltage and the ground potential;
directing current flow between the first input voltage and the ground potential;
resisting current flow between the second input voltage and the ground potential;
resisting and directing current flow between the second input voltage and the ground potential; and
resisting current flow between the reference voltage and the ground potential.

17. A method as defined in claim 16, further comprising resisting and directing current flow between the first input voltage and the ground potential.

18. A method as defined in claim 14, further comprising:
switching the power supply voltage in response to the output voltage;
switching in response to the first and second input voltages, respectively;
mirroring current towards the ground potential;
following the mirrored current towards the ground potential;
mirroring current from the power supply voltage; and
following the mirrored current from the power supply voltage.

19. A method as defined in claim 18 wherein the fifth, sixth, seventh, twelfth and thirteenth switching steps each comprises inverting.

20. A circuit as defined in claim 18 wherein none of the fifth through thirteenth switching steps comprises inverting.
